(19) United States
(12) Patent Application Publication
(10) Pub. No.: US 2025/0167075 A1
(43) Pub. Date: May 22, 2025

(54) SEMICONDUCTOR DEVICE AND METHODS OF MANUFACTURE

(71) Applicant: Taiwan Semiconductor Manufacturing Co., Ltd., Hsinchu (TW)

(72) Inventors: Yu-Jen Lien, Tainan City (TW); Chen-Hua Yu, Hsinchu (TW); Cheng-Chieh Hsieh, Tainan (TW); Kuo-Chung Yee, Taoyuan City (TW); Hung-Yi Kuo, Taipei City (TW); Ke-Han Shen, Chiayi City (TW)

(21) Appl. No.: 18/512,194

(22) Filed: Nov. 17, 2023

(51) Int. Cl. H01L 23/473; H01L 21/48; H01L 23/00; H01L 23/48

(52) U.S. Cl. CPC H01L 23/473; H01L 21/4871; H01L 23/481; H01L 24/08; H01L 24/80; H01L 2224/08225; H01L 2224/80895; H01L 2224/80896

(57) ABSTRACT

Semiconductor devices and methods of manufacture are presented herein. In accordance with some embodiments, a device includes a first semiconductor device, the first semiconductor device including a first interconnect structure, an integrated cooling structure bonded to the first interconnect structure, wherein the integrated cooling structure is configured for a working fluid to enter and exit the integrated cooling structure, a second semiconductor device including a second interconnect structure, the second semiconductor device bonded to the integrated cooling structure opposite the first interconnect structure, and a plurality of through substrate vias extending through the integrated cooling structure, wherein the plurality of through substrate vias electrically couple the first semiconductor device to the second semiconductor device.

### BACKGROUND

In wafer-to-wafer bonding technology, various methods have been developed to bond two package components (such as wafers) together. The available bonding methods include fusion bonding, eutectic bonding, direct metal bonding, hybrid bonding, and the like. In the fusion bonding, an oxide surface of a wafer is bonded to an oxide surface or a silicon surface of another wafer. In the eutectic bonding, two eutectic materials are placed together, and are applied with a high pressure and a high temperature. The eutectic materials are hence molten. When the melted eutectic materials are solidified, the wafers are bonded together. In the direct metal-to-metal bonding, two metal pads are pressed against each other at an elevated temperature, and the inter-diffusion of the metal pads causes the bonding of the metal pads. In the hybrid bonding, the metal pads of two wafers are bonded to each other through direct metal-to-metal bonding, and an oxide surface of one of the two wafers is bonded to an oxide surface or a silicon surface of the other wafer.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates a formation of a first bond layer over a first semiconductor device, in accordance with some embodiments.

FIG. 2 illustrates a bonding of a first cooling layer structure to the first semiconductor device, in accordance with some embodiments.

FIG. 3 illustrates a formation of first vias within the first cooling layer structure, in accordance with some embodiments.

FIG. 4A illustrates a formation of cavity and micropillars within the first cooling layer structure, in accordance with some embodiments.

FIG. 4B illustrates a cross-sectional view of the cavity and the micropillars within the first cooling layer structure, in accordance with some embodiments.

FIG. 5 illustrates a bonding of a second cooling layer structure to the first cooling layer structure, in accordance with some embodiments.

FIG. 6 illustrates a formation of openings through the second cooling layer structure into the cavity within the first cooling layer structure, in accordance with some embodiments.

FIG. 7 illustrates a bonding of a second semiconductor device to the second cooling layer structure, in accordance with some embodiments.

FIG. 8A illustrates an introduction of a coolant into the cavity, in accordance with some embodiments.

FIG. 8B illustrates a cross-sectional view of the cavity with the coolant surrounding the vias within micropillars, in accordance with some embodiments.

FIGS. 9-10 illustrate a formation of a semiconductor package with through vias formed after the bonding of the first cooling layer structure to the second cooling layer structure, in accordance with some embodiments.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Embodiments of the present disclosure advantageously providing an integrated micro-cooling (IMC) structure within a package, such as a system on integrated chip (SoIC) package or a 3D integrated chip (3DIC) package to provide improved cooling. Additionally, the IMC structure may utilize a working fluid (e.g., a coolant) flowing with turbulent flow allowing for increased temperature absorption and faster rate of heat transfer in order to more effectively remove heat from the package.

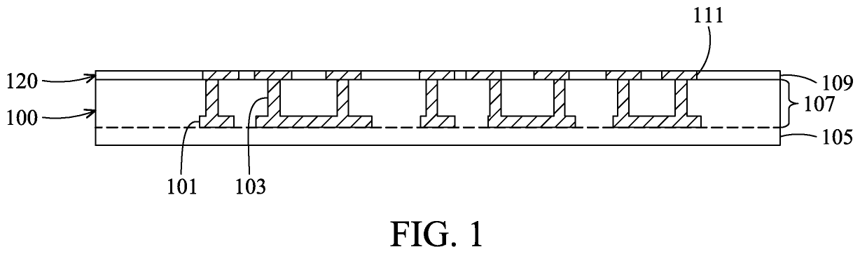

FIG. 1 illustrates a first semiconductor device 100 with metallization patterns 101 and vias 103. In some embodiments, the first semiconductor device 100 may be a high bandwidth memory (HBM) module, an xPU, a logic die, a CPU, a GPU, a SoC die, a MEMS die, a logic device, complementary metal oxide semiconductor (CMOS) device, micro-electro-mechanical systems (MEMS) device, integrated passive device (IPD), driver, or memory device such as memory cells including, and not limited to, Static Random Access Memory (SRAM) cells, Dynamic Random Access Memory (DRAM) Cells, Magneto-Resistive Random Access Memory (MRAM) cells, or the like. The first semiconductor device 100 may include other types of devices, combinations of these, or the like. Any suitable device with any suitable functionality, may be used, and all such devices are fully intended to be included within the scope of the embodiments. Although FIG. 1 only shows one layer of metallization patterns 101 and one layer of vias 103, it is understood that the first semiconductor device 100 may include more than one of metallization patterns 101 and more than one layer of vias 103.

In an embodiment, the first semiconductor device 100 includes a first substrate 105, which may be a semiconductor substrate, such as a silicon substrate, a silicon germanium substrate, a silicon carbon substrate, an III-V compound semiconductor substrate, or the like. A device area (not separately illustrated) is formed at the surface or inside first substrate 105. The device area may comprise active or passive devices, such as transistors, resistors, capacitors, diodes, and the like. In some embodiments, device area may comprise an encapsulated die (not separately illustrated).

In some embodiments, an interconnect structure 107 may be used to electrically connect various active and passive devices. Interconnect structure 107 may include insulating layers (not separately illustrated), such as an inter-layer dielectric (ILD) and/or inter-metal dielectric layers (IMD) and conductive features (e.g., the metallization patterns 101 and the vias 103) formed in alternating insulating layers over first substrate 105 using any suitable method. The interconnect structure 107 may connect various active and/or passive devices in device area of first substrate 105 to form functional circuits. The insulating layers may include low-k dielectric materials having k values, for example, lower than about 4.0 or even 2.8.

In some embodiments, the interconnect structure 107 comprises one or more layers of electrical routing (e.g., the metallization patterns 101 and/or the vias 103) in the interconnect structure 107 formed over the first substrate 105. The electrical routing may be formed of one or more layers of conductive lines in a dielectric (e.g., low-k dielectric material) material with conductive vias interconnecting the layers of conductive lines. For example, the electrical routing may include one to three layers of conductive lines. In other embodiments, the electrical routing may include a different number of layers of conductive lines. The conductive vias may extend through the dielectric to provide vertical connections between layers of conductive lines. The electrical routing may be formed through any suitable process (such as deposition, damascene, dual damascene, or the like).

In some embodiments, the electrical routing is formed using a damascene process in which a respective dielectric layer is patterned and etched utilizing photolithography techniques to form trenches corresponding to the desired pattern of metallization layers and/or vias. An optional diffusion barrier and/or optional adhesion layer may be deposited and the trenches may be filled with a conductive material. Suitable materials for the barrier layer includes titanium, titanium nitride, titanium oxide, tantalum, tantalum nitride, titanium oxide, or other alternatives, and suitable materials for the conductive material include copper, silver, gold, tungsten, aluminum, combinations thereof, or the like. In an embodiment, the metallization layers may be formed by depositing a seed layer of copper or a copper alloy, and filling the trenches by electroplating. A chemical mechanical planarization (CMP) process or the like may be used to remove excess conductive material from a surface of the respective dielectric layer and to planarize the surface for subsequent processing.

In some embodiments, the use of a damascene or dual damascene process can form electrical routing having a smaller pitch (e.g., “fine-pitch routing”), which can increase the density of the electrical routing and also may allow for improved conduction and connection reliability within the interconnect structure 107. Fine-pitch routing may have less surface roughness than other types of routing, and thus can reduce resistance experienced by higher-speed signals and also reduce signal loss (e.g., insertion loss) during high-speed operation.

FIG. 1 further illustrates a first bond layer 120 formed over the interconnect structure 107. In an embodiment, a first dielectric layer 109 is formed over the interconnect structure 107. Acceptable dielectric materials for the first dielectric layer 109 may include oxides such as silicon oxide or aluminum oxide; nitrides such as silicon nitride; carbides such as silicon carbide; the like; or combinations thereof such as silicon oxynitride, silicon oxycarbide, silicon carbonitride, silicon oxycarbonitride or the like. The first dielectric layer 109 may be formed by spin coating, lamination, chemical vapor deposition (CVD), or the like. The first dielectric layer 109 then is patterned using, e.g., a photolithographic masking and etching process, although any suitable patterning process may be utilized. The patterning forms openings (not separately illustrated) exposing conductive portions of the interconnect structure 107. In an embodiment, a conductive material is formed in the openings and over the first dielectric layer 109. As an example to form the conductive material, a seed layer (not separately illustrated) may be formed over the first dielectric layer 109 and in the openings extending through the first dielectric layer 109. In some embodiments, the seed layer is a metal layer, which may be a single layer or a composite layer comprising a plurality of sub-layers formed of different materials. In some embodiments, the seed layer comprises a titanium layer and a copper layer over the titanium layer. The seed layer may be formed using, for example, PVD or the like. The conductive material may then be formed on the seed layer. The conductive material may be formed by plating, such as electroplating or electroless plating, or the like. The conductive material may comprise a metal, like copper, titanium, tungsten, aluminum, or the like.

In an embodiment, first conductive connectors 111 are formed from the conductive material in the openings. In an embodiment, the first conductive connectors 111 are formed by removing excess material of the conductive material from a surface of the first dielectric layer 109 by, for example, a planarization process such as a chemical-mechanical polish (CMP), wherein the remaining conductive material in the openings of the first dielectric layer 109 forms the first conductive connectors 111. The first conductive connectors 111 provide an electrical contact point for external connection to the interconnect structure 107 for the integrated circuit devices to electrically couple to. In an embodiment, the first dielectric layer 109 and the first conductive connectors 111 forms the first bond layer 120 for which subsequent structures may be bonded to.

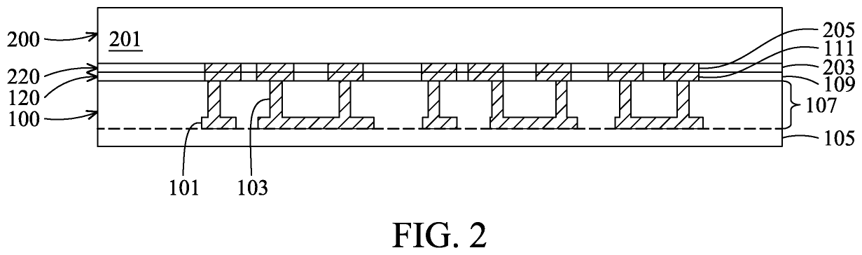

FIG. 2 illustrates a bonding of a first cooling structure layer 200 to the first semiconductor device 100. In an embodiment, the first cooling structure layer 200 may comprise of a first cooling structure substrate 201. In an embodiment, the first cooling structure substrate 201 may be formed from a silicon material. The silicon material may comprise silicon (e.g., a bulk silicon), silicon carbide, silicon oxide, silicon nitride, the like; or combinations thereof such as silicon oxynitride, silicon oxycarbide, silicon carbonitride, silicon oxycarbonitride or the like.

In an embodiment, a second bond layer 220 may be formed over the first cooling structure substrate 201. In an embodiment, the second bond layer 220 may comprise a second dielectric layer 203 and second conductive connectors 205. The second bond layer 220, including the second dielectric layer 203 and the second conductive connectors 205, may be formed in a similar manner and from similar materials as with respect to the formation of the first bond layer 120, including the formation of the first dielectric layer 109 and the formation of the first conductive connectors 111. However, any suitable process and materials may be utilized in the forming of the second bond layer 220.

In an embodiment, the first cooling structure substrate 201 and the second bond layer 220 formed over the first cooling structure substrate 201 may be flipped over and the second bond layer 220 may be placed in contact with the first bond layer 120. The second bond layer 220 may be bonded to the first bond layer 120 by a dielectric-to-dielectric and metal-to-metal bonding process performed between the second bond layer 220 and the first bond layer 120. In some embodiments, the dielectric-to-dielectric bonding process forms a direct bond (e.g. a fusion bond, such as an oxide-to-oxide bond) between the first dielectric layer 109 and the second dielectric layer 203. Further, the metal-to-metal bonding process may directly bond the first conductive connectors 111 of the first bond layer 120 to the second conductive connectors 205 of the second bond layer 220 through direct metal-to-metal bonding. The dielectric-to-dielectric bonding process may start with applying a surface treatment to either or both of the first dielectric layer 109 and the second dielectric layer 203 facilitating a dielectric-to-dielectric bond between the first dielectric layer 109 and the second dielectric layer 203 (e.g. a such as an oxide-to-oxide bond). The surface treatment may include a plasma treatment. The plasma treatment may be performed in a vacuum environment. After the plasma treatment, the surface treatment may further include a cleaning process (e.g., a rinse with deionized water, or the like) that may be applied to either or both of the first dielectric layer 109 and the second dielectric layer 203. The dielectric-to-dielectric and metal-to-metal bonding process may then proceed to aligning the second conductive connectors 205 of the second bond layer 220 to the first conductive connectors 111 of the first bond layer 120. Next, the dielectric-to-dielectric and metal-to-metal bonding process includes a pre-bonding step, during which the second bond layer 220 is put in contact with the first bond layer 120. The pre-bonding may be performed at room temperature (e.g., between about 21° C. and about 25° C.). The dielectric-to-dielectric and metal-to-metal bonding process continues with performing an anneal, for example, at a temperature between about 150° C. and about 400° C. for a duration between about 0.5 hours and about 3 hours, so that the first conductive connectors 111 (e.g., copper) and the second conductive connectors 205 (e.g., copper) inter-diffuses to each other, and hence the direct metal-to-metal bonding is formed, thereby bonding the first cooling structure layer 200 to the first semiconductor device 100.

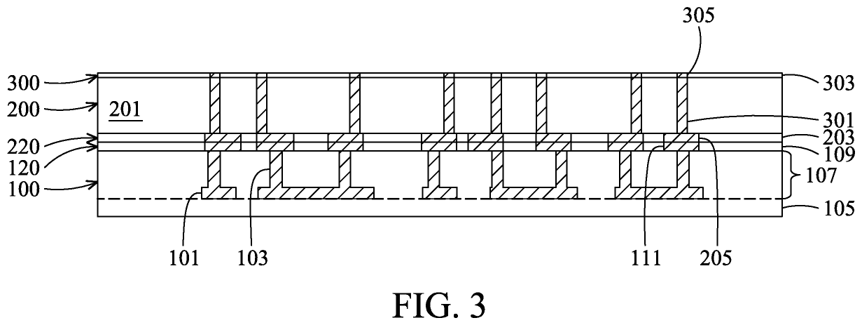

FIG. 3 illustrates the formation of first through substrate vias (TSVs) 301 through the first cooling structure substrate 201. In an embodiment the first TSVs 301 may be formed by initially forming TSV openings (not separately illustrated) into the first cooling structure substrate 201. The TSV openings may be formed by applying and developing a suitable photoresist (not shown), and etching portions of the first cooling structure substrate 201 that are exposed to the desired depth. Once the TSV openings have been formed within the first cooling structure substrate 201, the TSV openings may be lined with a liner. The liner may be, e.g., an oxide formed from tetraethylorthosilicate (TEOS) or silicon nitride, although any suitable dielectric material may alternatively be used. The liner may be formed using a plasma enhanced chemical vapor deposition (PECVD) process, although other suitable processes, such as physical vapor deposition or a thermal process, may alternatively be used.

Once the liner has been formed along the sidewalls and bottom of the TSV openings, a barrier layer (not separately illustrated) may be formed and the remainder of the TSV openings may be filled with a conductive material. The conductive material may comprise copper, although other suitable materials such as aluminum, alloys, doped polysilicon, combinations thereof, and the like, may alternatively be utilized. The conductive material may be formed by electroplating copper onto a seed layer (not separately illustrated), filling and overfilling the TSV openings. Once the TSV openings have been filled, excess liner, barrier layer, seed layer, and the conductive material outside of the TSV openings may be removed through a planarization process such as chemical mechanical polishing (CMP) to form the first TSVs 301, although any suitable removal process may be used.

FIG. 3 further illustrates a formation of a third bond layer 320. The third bond layer 320 may be formed over the first cooling structure substrate 201 and may comprise of a third dielectric layer 303 and third conductive connectors 305. In an embodiment, the third dielectric layer 303 and the third conductive connectors 305 may be formed in a similar manner and from similar materials as the first dielectric layer 109 or the second dielectric layer 203, and as the first conductive connectors 111 or the second conductive connectors 205. In this embodiment, the third conductive connectors 305 are formed in openings over the first TSVs 301 as to be physically and electrically coupled to the first TSVs 301. In an alternative embodiment, the third bond layer 320 is formed by forming the third dielectric layer 303 over the first cooling structure substrate 201 prior to the forming of the first TSVs 301. In this embodiment, openings are formed through both the third dielectric layer 303 and through the first cooling structure substrate 201 and the first TSVs 301 are then formed in a similar manner as described above but extending through the third dielectric layer 303.

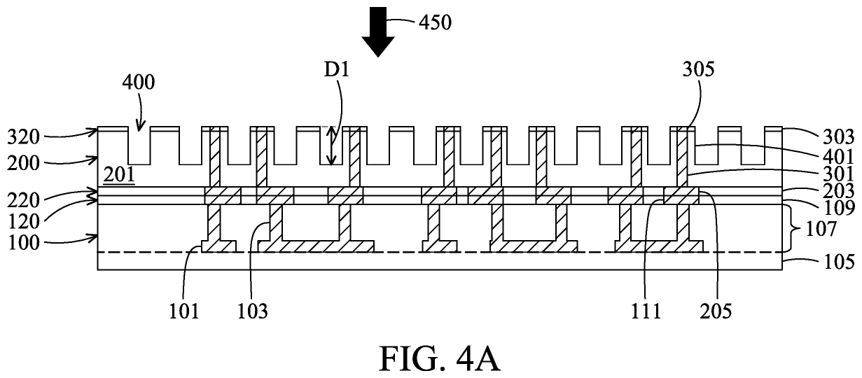

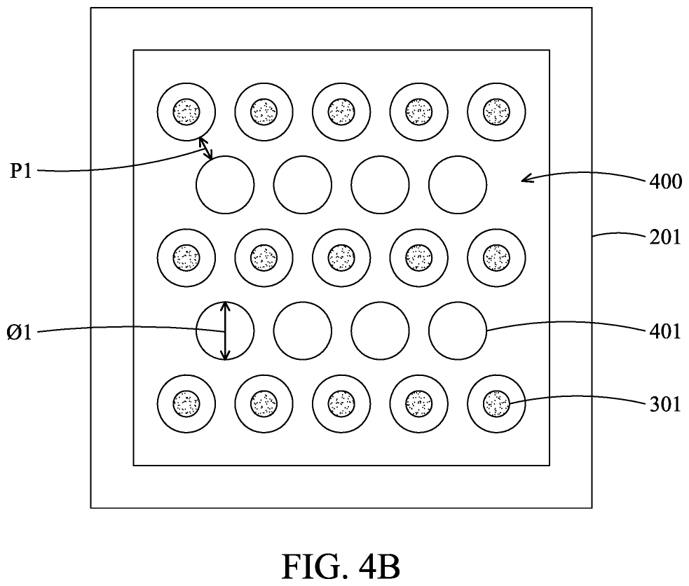

FIGS. 4A and 4B illustrate the formation of a cavity 400 in the first cooling structure layer 200. In an embodiment, the formation of the cavity 400 in the first cooling structure layer 200 forms micropillars 401 within the first cooling structure layer 200 from a remaining material of the first cooling structure substrate 201. In an embodiment, the cavity 400 may be formed by a removal process 450, which removes material from the first cooling structure substrate 201 as well as from the third dielectric layer 303. The removal of material from the first cooling structure substrate 201 and from the third dielectric layer 303 forms the cavity 400 within the first cooling structure layer 200 with remaining portions of material of the first cooling structure substrate 201 protruding into the cavity 400 forming the micropillars 401.

In an embodiment, the removal process 450 may be an etching process, such as a reactive ion etch (RIE), neutral beam etch (NBE), the like, or a combination thereof. The etching process may be anisotropic. In an embodiment, a pattern of the micropillars 401 may be formed during the removal process 450 by any suitable method. For example, the micropillars 401 may be formed using one or more photolithography processes to mask areas of the first cooling structure substrate 201 that are not removed during the removal process 450. In another embodiment, the cavity 400 and the micropillars 401 may be formed by the removal process 450 where the removal process 450 is a mechanical removal processes such as a drilling process. However, any suitable process may be used for the removal process 450 in forming the cavity 400 and the micropillars 401.

In an embodiment, the removal process 450 forms the micropillars 401, where the micropillars 401 serve provide multiple functions within the cavity 400. A first subset of the micropillars 401 include the first TSVs 301 and a second subset of the micropillars 401 do not contain the first TSVs 301. In an embodiment, the micropillars 401 may provide structural support for the first cooling structure layer 200 within the cavity 400. In an embodiment, the micropillars 401 provide obstructions to a flow of a subsequently inserted working fluid 801 (e.g., a liquid coolant), which allows the working fluid 801 to have turbulent flow. In an embodiment, the micropillars 401 provide structural support and physical isolation for the first TSVs 301 from the working fluid 801 while the working fluid 801 is passing through the cavity 400 in the first cooling structure layer 200.

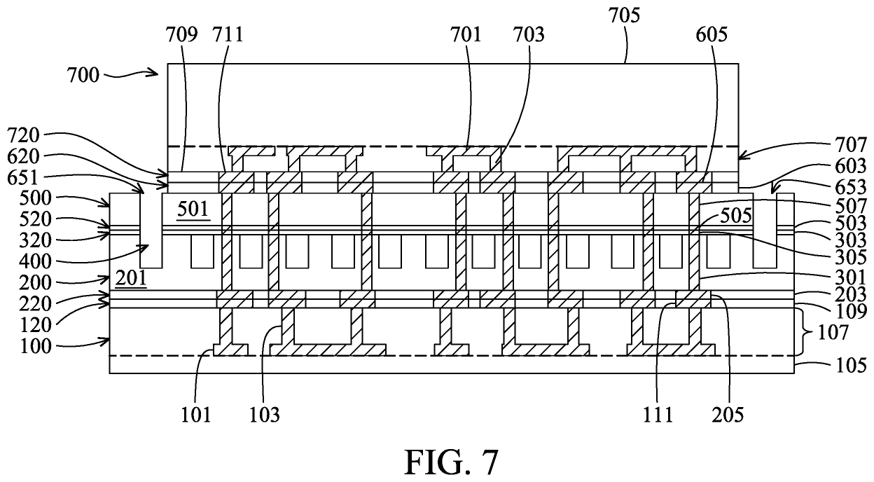

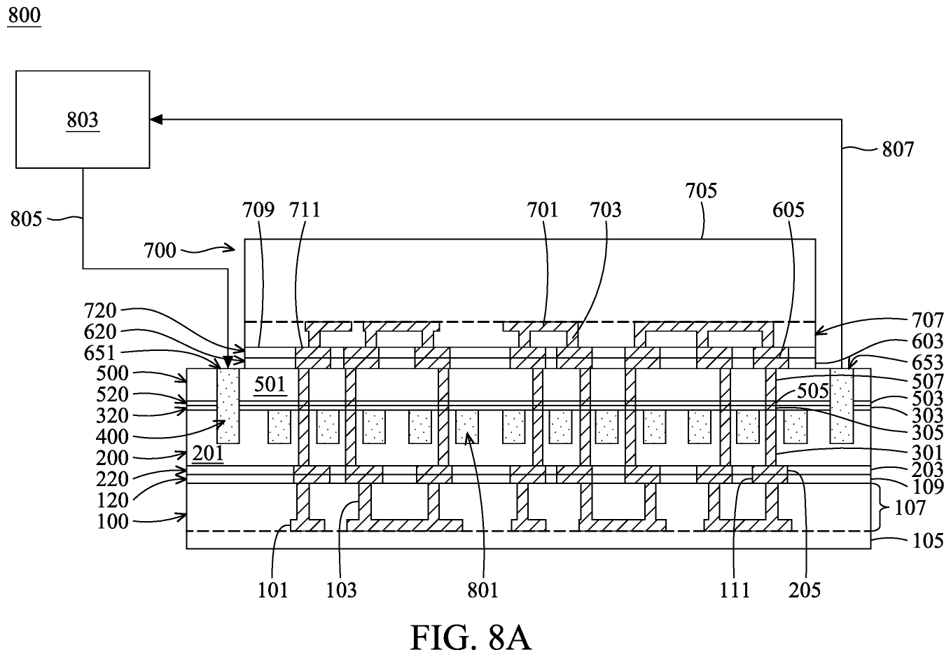

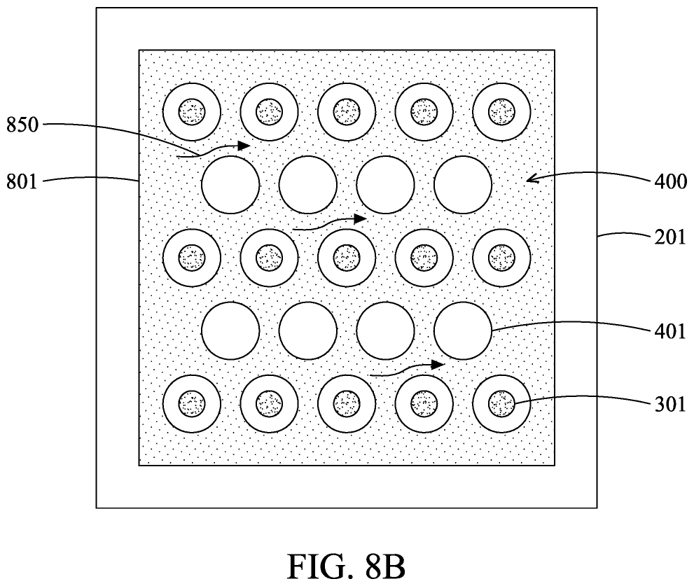

In an embodiment, the cavity 400 extends to a depth D1 in the first cooling structure layer 200. In some embodiments, the depth D1 may be in a range of 100 microns to 500 microns. In this embodiment, turbulent flow of the subsequently inserted working fluid 801 (discussed in greater detail below with respect to FIG. 8) may be achieved with a standard power pump (discussed in greater detail below with respect to FIG. 8) where the first depth D1 is 100 microns or greater. If the first depth D1 is greater than 500 microns, than a distance between the first semiconductor device 100 and subsequently attached devices (e.g., a second semiconductor device 700, illustrated in FIG. 7) may be too great and signal degradation between the first semiconductor device 100 and the second semiconductor device 700 may be inadequate. In other embodiments, the depth D1 may be in a range of 50 microns to 500 microns. In this embodiment, turbulent flow of the subsequently inserted working fluid 801 may be achieved with a high power pump (discussed in greater detail below with respect to FIG. 8) where the second depth D2 is 50 microns or greater. If the second depth D2 is greater than 500 microns, than a distance between the first semiconductor device 100 and the subsequently attached devices (e.g., a second semiconductor device 700, illustrated in FIG. 7) may be too great and signal degradation between the first semiconductor device 100 and the second semiconductor device 700 may be inadequate.

FIG. 4B illustrates a cross-sectional view of the first cooling structure layer 200 illustrated in FIG. 4A at cut through the cavity 400. In an embodiment, the micropillars 401 may be disposed in organized arrays (e.g., with a consistent pitch between each of the micropillars 401) of the first subset of the micropillars 401 that surround the first TSVs 301 and the second subset of the micropillars 401 that do not contain the first TSVs 301. In an alternative embodiment, the arrangement of the micropillars 401 may not be organized and may not be uniformly distributed. For example, a pitch between each of the micropillars 401 may vary. Further, in an embodiment, the micropillars 401 are illustrated as being formed to have a circular cross section, however, this is merely illustrative and the micropillars 401 may be formed to have cross sections of any suitable shape, such as a square shape, rectangular shape, tear-drop shape, the like, or a combination thereof.

The micropillars 401 may be formed to a first diameter ø1, where the first diameter ø1 may be in a range of 100 microns to 800 microns. Further, in an embodiment, the micropillars 401 may be formed to have a cross sectional area, the cross sectional area in a range of 7,850 square microns to 502,000 square microns. If the cross sectional area is below this range, than the micropillars 401 may not be large enough to provide structural support for the first cooling structure layer 200 within the cavity 400, to provide obstruction to the flow of the working fluid 801, or to provide structural support and physical isolation for the first TSVs 301 from the working fluid 801 while the working fluid 801 is passing through the cavity 400 in the first cooling structure layer 200 and if the cross sectional area is above this range, than the micropillars 401 may take up too much space within the cavity 400 resulting in undue obstruction of flow of the working fluid 801 within the cavity 400 which may result in undesired pressure being exerted upon an external pump 803 (discussed in greater detail below with respect to FIG. 8). In an embodiment, the micropillars 401 have a first pitch P1, wherein the first pitch P1 may be in a range of 200 microns to 600 microns. If the pitch between the micropillars 401 is less than the first pitch P1, than the flow of the working fluid 801 may be overly restricted. If the pitch between the micropillars 401 is greater than the first pitch P1, than the micropillars may not contribute to the turbulent flow of the working fluid 801 through the cavity 400 or provide adequate structural support to the first cooling structure layer 200.

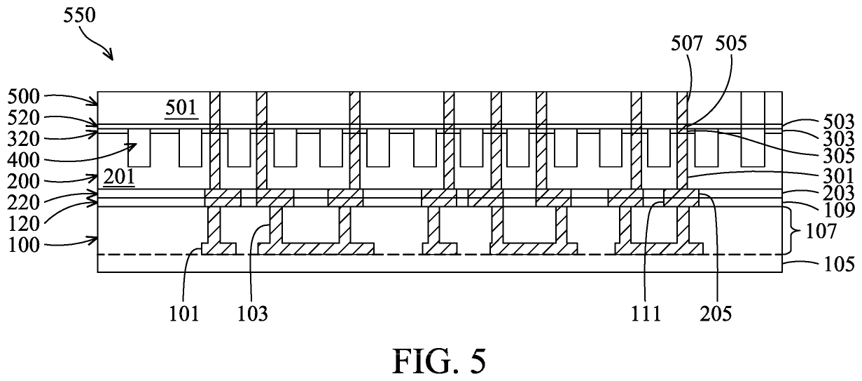

FIG. 5 illustrates a bonding of a second cooling structure layer 500 to the first cooling structure layer 200. In an embodiment, the second cooling structure layer 500 may comprise of a second cooling structure substrate 501. In an embodiment, the second cooling structure substrate 501 may be formed from a silicon material. The silicon material may comprise silicon (e.g., bulk silicon), silicon carbide, silicon oxide, silicon nitride, the like; or combinations thereof such as silicon oxynitride, silicon oxycarbide, silicon carbonitride, silicon oxycarbonitride or the like.

In an embodiment, a fourth bond layer 520 may be formed over the second cooling structure substrate 501. In an embodiment, the fourth bond layer 520 may comprise a fourth dielectric layer 503 and fourth conductive connectors 505. The fourth bond layer 520, including the fourth dielectric layer 503 and the fourth conductive connectors 505, may be formed in a similar manner and from similar materials as the third bond layer 320, with respect to the formation of the third dielectric layer 303 and the formation of the third conductive connectors 305. However, any suitable method and materials may be utilized to form the fourth bond layer 520.

In an embodiment, the second cooling structure substrate 501 and the fourth bond layer 520 formed over the second cooling structure substrate 501 may be flipped over and the fourth bond layer 520 may be placed in contact with the third bond layer 320. The fourth bond layer 520 may be bonded to the third bond layer 320 by a dielectric-to-dielectric and metal-to-metal bonding process performed between the fourth bond layer 520 and the third bond layer 320. In some embodiments, the dielectric-to-dielectric bonding process forms a direct bond (e.g. a fusion bond, such as an oxide-to-oxide bond) between the third dielectric layer 303 and the fourth dielectric layer 503. Further, the metal-to-metal bonding process may directly bond the third conductive connectors 305 of the third bond layer 320 to the fourth conductive connectors 505 of the fourth bond layer 520 through direct metal-to-metal bonding. In an alternative embodiment, the metal-to-metal bonding process may directly bond the fourth conductive connectors to the first TSVs 301 and the third conductive connectors 305 may be omitted. The dielectric-to-dielectric bonding process may start with applying a surface treatment to either or both of the third dielectric layer 303 and the fourth dielectric layer 503 facilitating a dielectric-to-dielectric bond between the third dielectric layer 303 and the fourth dielectric layer 503 (e.g. a such as an oxide-to-oxide bond). The surface treatment may include a plasma treatment. The plasma treatment may be performed in a vacuum environment. After the plasma treatment, the surface treatment may further include a cleaning process (e.g., a rinse with deionized water, or the like) that may be applied to either or both of the third dielectric layer 303 and the fourth dielectric layer 503. The dielectric-to-dielectric and metal-to-metal bonding process may then proceed to aligning the fourth conductive connectors 505 of the fourth bond layer 520 to either the third conductive connectors 305 of the third bond layer 320 or to the first TSVs 301. Next, the dielectric-to-dielectric and metal-to-metal bonding process includes a pre-bonding step, during which the third bond layer 320 is put in contact with the fourth bond layer 520. The pre-bonding may be performed at room temperature (e.g., between about 21° C. and about 25° C.). The dielectric-to-dielectric and metal-to-metal bonding process continues with performing an anneal, for example, at a temperature between about 150° C. and about 400° C. for a duration between about 0.5 hours and about 3 hours, so that the fourth conductive connectors 505 (e.g., copper) and either the third conductive connectors 305 (e.g., copper) or the first TSVs 301 inter-diffuses to each other, and hence the direct metal-to-metal bonding is formed, thereby bonding the first cooling structure layer 200 to the second cooling structure layer 500.

FIG. 5 further illustrates the formation of second TSVs 507 through the second cooling structure substrate 501. In an embodiment the second TSVs 507 may be formed by initially forming TSV openings (not separately illustrated) into the second cooling structure substrate 501. The TSV openings may be formed by applying and developing a suitable photoresist (not shown), and removing portions of the second cooling structure substrate 501 that are exposed to the desired depth. Once the TSV openings have been formed within the second cooling structure substrate 501, the TSV openings may be lined with a liner. The liner may be, e.g., an oxide formed from tetraethylorthosilicate (TEOS) or silicon nitride, although any suitable dielectric material may alternatively be used. The liner may be formed using a plasma enhanced chemical vapor deposition (PECVD) process, although other suitable processes, such as physical vapor deposition or a thermal process, may alternatively be used.

Once the liner has been formed along the sidewalls and bottom of the TSV openings, a barrier layer (not separately illustrated) may be formed and the remainder of the TSV openings may be filled with a conductive material. The conductive material may comprise copper, although other suitable materials such as aluminum, alloys, doped polysilicon, combinations thereof, and the like, may alternatively be utilized. The conductive material may be formed by electroplating copper onto a seed layer (not separately illustrated), filling and overfilling the TSV openings. Once the TSV openings have been filled, excess liner, barrier layer, seed layer, and the conductive material outside of the TSV openings may be removed through a planarization process such as chemical mechanical polishing (CMP) to form the second TSVs 507, although any suitable removal process may be used.

In an embodiment, following the bonding of the first cooling structure layer 200 to the second cooling structure layer 500, the resulting structure comprising of the first cooling structure layer 200, the cavity 400, the micropillars 401, and the second cooling structure layer 500 may be referred to as an integrated micro-cooler (IMC) structure 550. The IMC structure 550 allowing for the introduction of the working fluid 8o1 into the cavity 400 such that the working fluid 8o1 may flow in between the first semiconductor device 100 and the second semiconductor device 700 in order to dissipate and remove heat generated from the first semiconductor device 100 and the second semiconductor device 700.

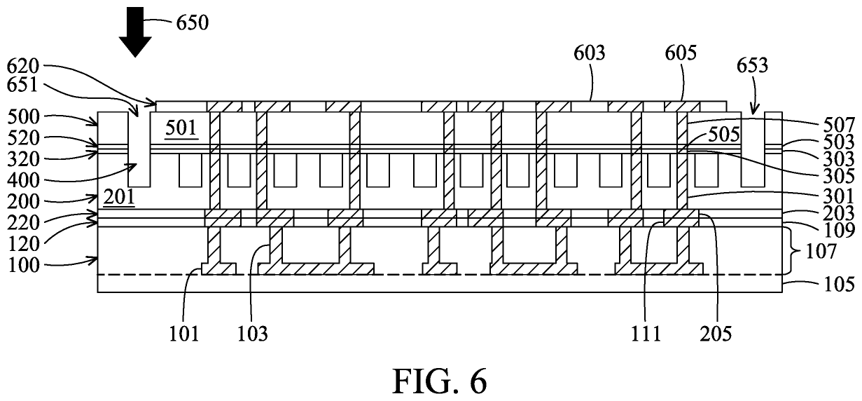

FIG. 6 illustrates a formation of a fifth bond layer 620 over the second cooling structure layer 500. In an embodiment, a fifth dielectric layer 603 is formed over the second cooling structure substrate 501. Acceptable dielectric materials for the fifth dielectric layer 603 may include oxides such as silicon oxide or aluminum oxide; nitrides such as silicon nitride; carbides such as silicon carbide; the like; or combinations thereof such as silicon oxynitride, silicon oxycarbide, silicon carbonitride, silicon oxycarbonitride or the like. The fifth dielectric layer 603 may be formed by spin coating, lamination, chemical vapor deposition (CVD), or the like. The fifth dielectric layer 603 may then be patterned using, e.g., a photolithographic masking and etching process, although any suitable patterning process may be utilized. The patterning forms openings (not separately illustrated). In an embodiment, a conductive material is formed in the openings and over the fifth dielectric layer 603. As an example to form the conductive material, a seed layer (not separately illustrated) may be formed over the fifth dielectric layer 603 and in the openings extending through the fifth dielectric layer 603. In some embodiments, the seed layer is a metal layer, which may be a single layer or a composite layer comprising a plurality of sub-layers formed of different materials. In some embodiments, the seed layer comprises a titanium layer and a copper layer over the titanium layer. The seed layer may be formed using, for example, PVD or the like. The conductive material may then be formed on the seed layer. The conductive material may be formed by plating, such as electroplating or electroless plating, or the like. The conductive material may comprise a metal, like copper, titanium, tungsten, aluminum, or the like.

In an embodiment, fifth conductive connectors 605 are formed from the conductive material in the openings. In an embodiment, the fifth conductive connectors 605 are formed by removing excess material of the conductive material from a surface of the fifth dielectric layer 603 by, for example, a planarization process such as a chemical-mechanical polish (CMP), wherein the remaining conductive material in the openings of the fifth dielectric layer 603 forms the fifth conductive connectors 605. In an embodiment, the fifth dielectric layer 603 and the fifth conductive connectors 605 forms the fifth bond layer 620. Further, in an embodiment, the fifth conductive connectors 605 are physically and electrically coupled to the second TSVs 507.

FIG. 6 further illustrates a second removal process 650. In an embodiment, the second removal process 650 may occur after the formation of the fifth bond layer 620. The second removal process 650 removes material from the second cooling structure substrate 501 as well as from the fourth dielectric layer 503 to form an inlet port 651 and an outlet port 653 providing access to the cavity 400. In an embodiment, the inlet port 651 and the outlet port 653 are on opposing sides of the second cooling structure layer 500. While the inlet port 651 is shown on the left side of the second cooling structure layer 500 and the outlet port 653 is shown on the right side of the second cooling structure layer 500, this is merely illustrative and the inlet port 651 and the outlet port 653 may be in any suitable orientation. The second removal process 650 may be an etching process like the processes described above with respect to the removal process 450 or may be a mechanical processes like the processes described above with respect to the removal process 450.

FIG. 7 illustrates a second semiconductor device 700 with metallization patterns 701 and vias 703. In some embodiments, the second semiconductor device 700 may be a high bandwidth memory (HBM) module, an xPU, a logic die, a CPU, a GPU, a SoC die, a MEMS die, a logic device, complementary metal oxide semiconductor (CMOS) device, micro-electro-mechanical systems (MEMS) device, integrated passive device (IPD), driver, or memory device such as memory cells including, and not limited to, Static Random Access Memory (SRAM) cells, Dynamic Random Access Memory (DRAM) Cells, Magneto-Resistive Random Access Memory (MRAM) cells, or the like. The first semiconductor device 100 may include other types of devices, combinations of these, or the like. Any suitable device with any suitable functionality, may be used, and all such devices are fully intended to be included within the scope of the embodiments.

In an embodiment, the second semiconductor device 700 includes a second substrate 705, which may be a semiconductor substrate, such as a silicon substrate, a silicon germanium substrate, a silicon carbon substrate, an III-V compound semiconductor substrate, or the like. A device area (not separately illustrated) is formed at the surface or inside second substrate 705. The device area may comprise active or passive devices, such as transistors, resistors, capacitors, diodes, and the like. In some embodiments, device area may comprise an encapsulated die (not separately illustrated).

In some embodiments, a second interconnect structure 707 may be used to redistribute connections between various active and passive devices. The second interconnect structure 707 may include insulating layers (not separately illustrated), such as an inter-layer dielectric (ILD) and/or inter-metal dielectric layers (IMD) and conductive features (e.g., the metallization patterns 701 and the vias 703) formed in alternating layers over second substrate 705 using any suitable method. The second interconnect structure 707 may connect various active and/or passive devices in device area of second substrate 705 to form functional circuits. The insulating layers may include low-k dielectric materials having k values, for example, lower than about 4.0 or even 2.8.

In some embodiments, the second interconnect structure 707 comprises one or more layers of electrical routing (e.g., the metallization patterns 701 and/or the vias 703) in the second interconnect structure 707 formed over the second substrate 705. The electrical routing may be formed of one or more layers of conductive lines in a dielectric (e.g., low-k dielectric material) material with conductive vias interconnecting the layers of conductive lines. For example, the electrical routing may include one to three layers of conductive lines. In other embodiments, the electrical routing may include a different number of layers of conductive lines. The conductive vias may extend through the dielectric to provide vertical connections between layers of conductive lines. The electrical routing may be formed through any suitable process (such as deposition, damascene, dual damascene, or the like).

In some embodiments, the electrical routing is formed using a damascene process in which a respective dielectric layer is patterned and etched utilizing photolithography techniques to form trenches corresponding to the desired pattern of metallization layers and/or vias. An optional diffusion barrier and/or optional adhesion layer may be deposited and the trenches may be filled with a conductive material. Suitable materials for the barrier layer includes titanium, titanium nitride, titanium oxide, tantalum, tantalum nitride, titanium oxide, or other alternatives, and suitable materials for the conductive material include copper, silver, gold, tungsten, aluminum, combinations thereof, or the like. In an embodiment, the metallization layers may be formed by depositing a seed layer of copper or a copper alloy, and filling the trenches by electroplating. A chemical mechanical planarization (CMP) process or the like may be used to remove excess conductive material from a surface of the respective dielectric layer and to planarize the surface for subsequent processing.

In some embodiments, the use of a damascene or dual damascene process can form electrical routing having a smaller pitch (e.g., “fine-pitch routing”), which can increase the density of the electrical routing and also may allow for improved conduction and connection reliability within the second interconnect structure 707. Fine-pitch routing may have less surface roughness than other types of routing, and thus can reduce resistance experienced by higher-speed signals and also reduce signal loss (e.g., insertion loss) during high-speed operation.

FIG. 7 further illustrates a sixth bond layer 720 formed over the second interconnect structure 707. In an embodiment, the sixth bond layer 720 may comprise a sixth dielectric layer 709 and sixth conductive connectors 711. The sixth bond layer 720, including the sixth dielectric layer 709 and the sixth conductive connectors 711, may be formed in a similar manner and from similar materials as the first bond layer 120, with respect to the formation of the first dielectric layer 109 and the formation of the first conductive connectors 111. However, any suitable method and materials may be utilized to form the sixth bond layer 720.

In an embodiment, the second semiconductor device 700 and the sixth bond layer 720 are flipped over so that the sixth bond layer 720 faces the fifth bond layer 620. The sixth bond layer 720 may be bonded to the fifth bond layer 620 by a dielectric-to-dielectric and metal-to-metal bonding process performed between the sixth bond layer 720 and the fifth bond layer 620. In some embodiments, the dielectric-to-dielectric bonding process forms a direct bond (e.g. a fusion bond, such as an oxide-to-oxide bond) between the sixth dielectric layer 709 and the fifth dielectric layer 603. Further, the metal-to-metal bonding process may directly bond the sixth conductive connectors 711 of the sixth bond layer 720 to the fifth conductive connectors 605 of the fifth bond layer 620 through direct metal-to-metal bonding. The dielectric-to-dielectric bonding process may start with applying a surface treatment to either or both of the sixth dielectric layer 709 and the fifth dielectric layer 603 facilitating a dielectric-to-dielectric bond between the sixth dielectric layer 709 and the fifth dielectric layer 603 (e.g. a such as an oxide-to-oxide bond). The surface treatment may include a plasma treatment. The plasma treatment may be performed in a vacuum environment. After the plasma treatment, the surface treatment may further include a cleaning process (e.g., a rinse with deionized water, or the like) that may be applied to either or both of the sixth dielectric layer 709 and the fifth dielectric layer 603. The dielectric-to-dielectric and metal-to-metal bonding process may then proceed to aligning the sixth conductive connectors 711 of the sixth bond layer 720 to the fifth conductive connectors 605 of the fifth bond layer 620. Next, the dielectric-to-dielectric and metal-to-metal bonding process includes a pre-bonding step, during which the sixth bond layer 720 is put in contact with the fifth bond layer 620. The pre-bonding may be performed at room temperature (e.g., between about 21° C. and about 25° C.). The dielectric-to-dielectric and metal-to-metal bonding process continues with performing an anneal, for example, at a temperature between about 150° C. and about 400° C. for a duration between about 0.5 hours and about 3 hours, so that the sixth conductive connectors 711 (e.g., copper) and the fifth conductive connectors 605 (e.g., copper) inter-diffuses to each other, and hence the direct metal-to-metal bonding is formed, thereby bonding the second cooling structure layer 500 to the second semiconductor device 700.

In an embodiment, following the bonding of the second semiconductor device 700 to the second cooling structure layer 500, the resulting structure comprising of the first semiconductor device 100, the IMC structure 550, and the second semiconductor device 700 may be referred to as a first semiconductor package 750. In an embodiment, the first semiconductor package 750 may be a system on integrated chip (SoIC) package. The SoIC package having the IMC structure 550 disposed between the first semiconductor device 100 and the second semiconductor device 700 allows for improved heat dissipation from the first semiconductor package 750.

FIG. 8A illustrates an introduction of a coolant system 800 to the first semiconductor package 750. In an embodiment, the first coolant system comprises of an inlet tube 805, an outlet tube 807, the external pump 803, and the working fluid 801. In an embodiment, the inlet tube 805 is fixed to the inlet port 651, the outlet tube 807 is fixed to the outlet port 653, and the external pump 803 pumps the working fluid 801 through the inlet tube 805 into the cavity 400 through the inlet port 651 and through the cavity 400 out through the outlet port 653 into the outlet tube 807. In an embodiment, the external pump 803 may have multiple inlet tubes 805 connected to multiple semiconductor packages and multiple outlet tubes 807 returning from these multiple semiconductor packages where a flow splitter is used to split the working fluid 801 being pumped by the external pump 803 into the multiple semiconductor packages.

In an embodiment, the working fluid 801 may be a cooling liquid such as water, a glycol water solution, or the like. The working fluid 801 enters the inlet port 651 at a first temperature, flows through the cavity 400 and exits at the outlet port 653 at a second temperature. In an embodiment where the working fluid 801 is water, the first temperature may be in a range of 0° C. to 40° C. In an embodiment where the working fluid 801 is a glycol water solution, the first temperature may be in a range of −49° C. to 40° C. In both embodiments, the second temperature of the working fluid 801 leaving through the outlet port 653 is at a higher temperature than the first temperature of the working fluid 801 entering at the inlet port 651. The first semiconductor package 750 may have an operating temperature resulting from heat being generated by the first semiconductor device 100 and heat being generated by the second semiconductor device 700. In an embodiment, the working fluid 801 is pumped into the cavity 400 by the external pump 803, the working fluid 801 being at the first temperature, where the first temperature is less than the operating temperature of the first semiconductor package 750. While the working fluid 801 is passing through the cavity 400 the working fluid 801 absorbs (transfers) heat from the first semiconductor package 750 due to the temperature differential between the operating temperature of the first semiconductor package 750 and a lower temperature of the working fluid 801. In an embodiment, when the working fluid 801 exits the cavity 400 the heat absorbed by the working fluid 801 from the first semiconductor package 750 causes a temperature of the working fluid 801 to raise from the first temperature to the second temperature. The heat transferred to the working fluid 801 from the first semiconductor package 750 as the working fluid 801 passes through the cavity 400 reduces the operating temperature of the first semiconductor package 750. In an embodiment, the working fluid 801 at the second temperature after exiting the cavity 400 may then dissipate heat into an environment outside the first semiconductor package 750. By reducing the operating temperature of the first semiconductor package 750, the first semiconductor package 750 may have improved performance, efficiency, and reliability.

FIG. 8B illustrates a cross-sectional view of the IMC structure 550 illustrated in FIG. 8A at cut through the cavity 400. In an embodiment, where the cavity 400 has the depth D1 that is at least 100 microns, than the external pump 803 may be a standard pump with an operating power of greater than 0 watts to 10 watts in order to provide enough power to pump the working fluid 801 through the cavity 400 around the micropillars 401 at a suitable flow profile (e.g., where the flow profile of the working fluid 801 through the cavity is a turbulent flow profile). In an embodiment, where the cavity 400 has the depth D1 that is at least 50 microns, where the depth may be less than 100 microns, than the external pump 803 may be a high pressure pump with an operating power of greater than 0 watts to 20 watts in order to provide enough power to pump the working fluid 801 through the cavity 400 around the micropillars 401 at a suitable flow profile (e.g., where a flow profile 850 of the working fluid 801 through the cavity is a turbulent flow profile).

The ability of the working fluid 801 to absorb heat is impacted by a multitude of factors. One such factor is the flow profile 850 of the working fluid 801. The flow profile 850 of the working fluid 801 is in part characterized by the inertial forces and viscous forces within the flow profile 850 of the working fluid 801. The flow profile 850 of the working fluid 801 may be characterized by a ratio of the inertial forces to the viscous forces within the flow, this ratio is referred to as the Reynolds number. The Reynolds number characterizes the flow profile 850 from laminar flow to turbulent flow. At turbulent flow, the flow profile 850 is dominated by the inertial forces as opposed to the viscous forces. At turbulent flow the heat transfer coefficient of the working fluid 801 is greater than the heat transfer coefficient of the working fluid 801 at laminar flow. In an embodiment, the number and pitch of the micropillars 401 within the cavity 400, the shape of the micropillars 401 obstructing the flow profile 850 of the working fluid, the rate of flow of the working fluid 801 through the cavity 400 generated by the external pump 803, and the depth D1 of the cavity, all contribute to driving the flow profile 850 of the working fluid 801 to a turbulent flow profile and thereby increasing the heat transfer coefficient of the working fluid 801. By increasing the heat transfer coefficient of the working fluid 801, the working fluid 801 is able to absorb heat at a faster rate from the first semiconductor package 750 as it passes through the cavity 400, thereby increasing the effectiveness of the IMC structure 550 in lowering the operating temperature of the first semiconductor package 750. In an embodiment, the IMC structure 550 is configured to produce a turbulent flow for the flow profile 850 for the working fluid 801 as the working fluid 801 passes through the cavity 400 (e.g., a Reynolds number of 4,000 or greater).

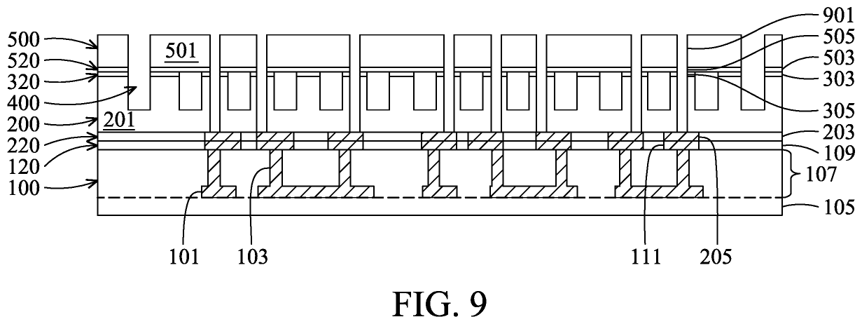

FIG. 9 illustrates an embodiment where the second cooling structure layer 500 is bounded to the first cooling structure layer 200 prior to forming any through substrate vias in either structure. In this embodiment, the structures described in FIGS. 1-5 are formed in similar manners and in similar processes as discussed above with the exception that the first TSVs 301 is not formed through the first cooling structure layer 200 and the second TSVs 507 is not formed through the second cooling structure layer 500. In this embodiment, following the bonding of the second cooling structure layer 500 to the first cooling structure layer 200 forming the IMC structure 550, first holes 901 are formed through both the first cooling structure layer 200 and the second cooling structure layer 500. In an embodiment, the first holes 901 are formed in a similar manner as discussed above with the formation of the openings used to form the first TSVs 301. In another embodiment, the first holes 901 are formed through a mechanical processes, such as a drilling process. In this embodiment, the third bond layer 320 and the fourth bond layer 520 may utilize metal dummy pads in order to form the metal-to-metal bonds as discussed above.

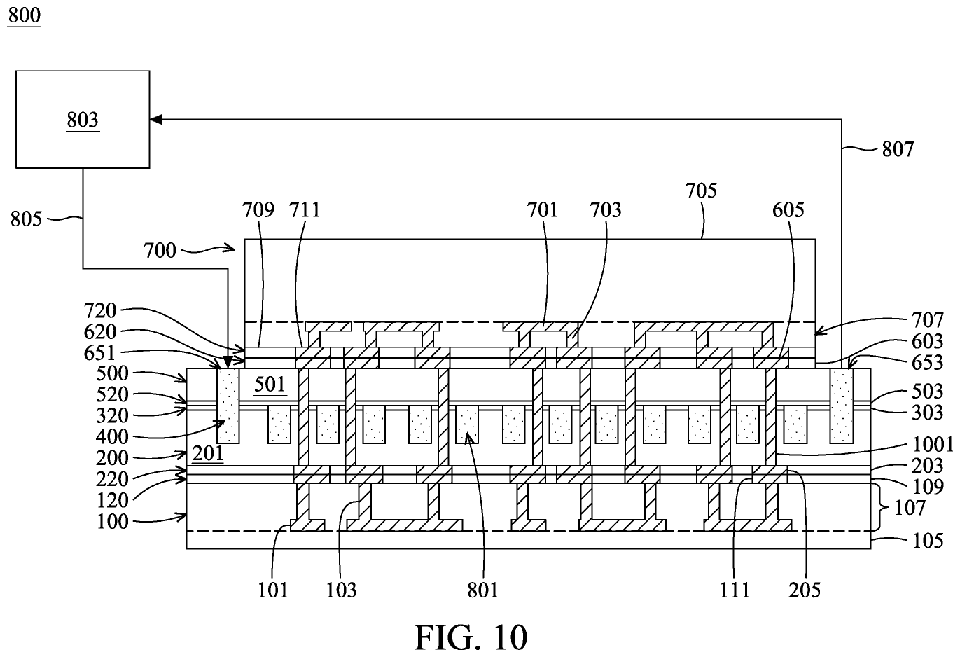

FIG. 10 illustrates the first semiconductor package 750 in an embodiment where the first TSVs 301 and the second TSVs 507 are replaced with third TSVs 1001 formed in the first holes 901 discussed in FIG. 9. In an embodiment, the third TSVs 1001 are formed in a similar manner and from similar materials as discussed above with respect to the first TSVs 301.

In some embodiments, structures of the IMC structure 550, structures of the first semiconductor device 100, and structures of the second semiconductor device 700 can be individually formed, and then bonded together by wafer-to-wafer bonding, chip-to-wafer bonding or chip-to-chip bonding.

Benefits may be achieved by forming the IMC structure 550 in between two semiconductor devices (e.g., the first semiconductor device 100, and the second semiconductor device 700) by allowing for fast heat transfer out of the first semiconductor package 750. Where the first semiconductor package 750 is an SoIC package or a 3DIC package, these packages are high performance computing packages with power outputs ranging between 1,000 watts to 5,000 watts. By having the IMC structure 550 in the middle of the first semiconductor package 750 as opposed to a heat dissipating structure on the exterior of the first semiconductor package 750, heat generated by the first semiconductor device 100 is able to be dissipated out of the first semiconductor package 750 without having to travel through the entirety of the first semiconductor package 750. Additionally, by utilizing the working fluid 801 within the coolant system 800, the high specific heat associated with the working fluid 801 and the ability to introduce the working fluid 801 at significantly lower temperatures than the operating temperature of the first semiconductor package 750, significant amount of heat is able to be removed by the working fluid 801, thereby improving the efficiency and reliability of the first semiconductor package 750. Further, by forming the cavity 400 to specific depths (e.g., the first depth D1) with specific pumps (e.g., the standard pump, and the high pressure pump) around the micropillars 401 allow for turbulent flow of the working fluid 801 is able to be achieved within the cavity 400. The significance of turbulent flow of the working fluid 801 within the 400 is that a fluid flowing at turbulent flow possesses particles with increased transverse motion which increases the rate of heat transfer by the fluid allowing for the working fluid 801 to carry away even more heat generated by the first semiconductor package 750 and allowing for lower operating temperatures at higher power density packages.

In accordance with some embodiments, a device includes a first semiconductor device, the first semiconductor device including a first interconnect structure, an integrated cooling structure bonded to the first interconnect structure, wherein the integrated cooling structure is configured for a working fluid to enter and exit the integrated cooling structure, a second semiconductor device including a second interconnect structure, the second semiconductor device bonded to the integrated cooling structure opposite the first interconnect structure, and a plurality of through substrate vias extending through the integrated cooling structure, wherein the plurality of through substrate vias electrically couple the first semiconductor device to the second semiconductor device. In an embodiment, wherein the integrated cooling structure includes an inlet port and an outlet port, both the inlet port and the outlet port connected to a cavity within the integrated cooling structure. In an embodiment, further including an external pump, an inlet tube, a first side of the inlet tube attached to the external pump, and a second side of the inlet tube attached to the inlet port, wherein the inlet tube contains the working fluid, and an outlet tube, a first side of the outlet tube attached to the outlet port, and a second side of the outlet tube attached to the external pump, wherein the outlet tube contains the working fluid. In an embodiment, wherein the integrated cooling structure includes a cavity, wherein the cavity is configured to permit the working fluid to flow through the cavity, and micropillars, wherein the micropillars extend from a first side of the cavity to a second side of the cavity, wherein the micropillars are configured to obstruct the flow of the working fluid through the cavity. In an embodiment, wherein a first subset of the micropillars are free from the plurality of through substrate vias and a second subset of the micropillars each surround one of the plurality of through substrate vias. In an embodiment, wherein the micropillars have a tear-drop cross section in a top down view. In an embodiment, wherein the working fluid includes a glycol solution or water.

In accordance with some embodiments, a method includes attaching a first substrate to a first semiconductor device, etching a cavity within the first substrate; wherein the etching the cavity forms micropillars within the cavity, the micropillars formed from a material of the first substrate, attaching a second substrate to the first substrate opposite the first semiconductor device, wherein the attaching the second substrate to the first substrate seals the cavity forming an integrated cooling structure configured to accommodate a liquid coolant, and attaching a second semiconductor device to the integrated cooling structure opposite the first semiconductor device. In an embodiment, further including forming an inlet port through the second substrate into the cavity, the inlet port adjacent to a first side of the second semiconductor device, and forming an outlet port through the second substrate into the cavity, the outlet port adjacent to a second side of the second semiconductor device, the second side being on an opposite side of the second semiconductor device than the first side. In an embodiment, further including attaching an inlet tube to the inlet port, attaching an outlet tube to the outlet port, and pumping a liquid coolant through the inlet tube into the cavity, around the micropillars and out through the outlet tube. In an embodiment, wherein the liquid coolant has a first temperature at the inlet tube and a second temperature at the outlet tube, wherein the second temperature is greater than the first temperature. In an embodiment, wherein during the pumping the liquid coolant through the inlet tube into the cavity, around the micropillars and out through the outlet tube, the liquid coolant has a turbulent flow around the micropillars within the cavity. In an embodiment, wherein a first subset of the micropillars are formed containing a via extending through the micropillars and a second subset of the micropillars are formed without containing a via. In an embodiment, wherein each one of the micropillars are spaced at differing distances from each other one of the micropillars within the cavity. In an embodiment, wherein the liquid coolant includes a glycol solution or water.

In accordance with some embodiments, an apparatus includes a first semiconductor package including a first semiconductor device, a second semiconductor device, and an integrated micro-cooling structure disposed between the first semiconductor device and the second semiconductor device, a pumping system attached to the first semiconductor package, the pumping system including a pump, a first tube, wherein a first side of the first tube is attached to the pump and a second side of the first tube is attached to the integrated micro-cooling structure, and a second tube, wherein a first side of the second tube is attached to the integrated micro-cooling structure and a second side of the second tube is attached to the pump, and a liquid coolant, wherein the liquid coolant is contained within the pumping system and within a cavity within the integrated micro-cooling structure. In an embodiment, wherein the pump has a pumping power of 10 or less watts. In an embodiment, wherein the pumping system is configured to accommodate the liquid coolant at a first temperature in the first tube and at a second temperature in the second tube, the second temperature being higher than the first temperature. In an embodiment, wherein the pumping system is configured to accommodate the liquid coolant with a Reynolds number greater than 4,000 within the cavity. In an embodiment, wherein the pumping system is attached to a second semiconductor package.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A device comprising:
a first semiconductor device, the first semiconductor device comprising a first interconnect structure;
an integrated cooling structure bonded to the first interconnect structure, wherein the integrated cooling structure is configured for a working fluid to enter and exit the integrated cooling structure;
a second semiconductor device comprising a second interconnect structure, the second semiconductor device bonded to the integrated cooling structure opposite the first interconnect structure; and
a plurality of through substrate vias extending through the integrated cooling structure, wherein the plurality of through substrate vias electrically couple the first semiconductor device to the second semiconductor device.

2. The device of claim 1, wherein the integrated cooling structure comprises an inlet port and an outlet port, both the inlet port and the outlet port connected to a cavity within the integrated cooling structure.

3. The device of claim 2, further comprising:
an external pump;
an inlet tube, a first side of the inlet tube attached to the external pump, and a second side of the inlet tube attached to the inlet port, wherein the inlet tube contains the working fluid; and
an outlet tube, a first side of the outlet tube attached to the outlet port, and a second side of the outlet tube attached to the external pump, wherein the outlet tube contains the working fluid.

4. The device of claim 1, wherein the integrated cooling structure comprises:
a cavity, wherein the cavity is configured to permit the working fluid to flow through the cavity; and
micropillars, wherein the micropillars extend from a first side of the cavity to a second side of the cavity, wherein the micropillars are configured to obstruct the flow of the working fluid through the cavity.

5. The device of claim 4, wherein a first subset of the micropillars are free from the plurality of through substrate vias and a second subset of the micropillars each surround one of the plurality of through substrate vias.

6. The device of claim 4, wherein the micropillars have a tear-drop cross section in a top down view.

7. The device of claim 1, wherein the working fluid comprises a glycol solution or water.

8. A method comprising:
attaching a first substrate to a first semiconductor device;
etching a cavity within the first substrate; wherein the etching the cavity forms micropillars within the cavity, the micropillars formed from a material of the first substrate;
attaching a second substrate to the first substrate opposite the first semiconductor device, wherein the attaching the second substrate to the first substrate seals the cavity forming an integrated cooling structure configured to accommodate a liquid coolant; and
attaching a second semiconductor device to the integrated cooling structure opposite the first semiconductor device.

9. The method of claim 8, further comprising:
forming an inlet port through the second substrate into the cavity, the inlet port adjacent to a first side of the second semiconductor device; and
forming an outlet port through the second substrate into the cavity, the outlet port adjacent to a second side of the second semiconductor device, the second side being on an opposite side of the second semiconductor device than the first side.

10. The method of claim 9, further comprising:
attaching an inlet tube to the inlet port;
attaching an outlet tube to the outlet port; and
pumping a liquid coolant through the inlet tube into the cavity, around the micropillars and out through the outlet tube.

11. The method of claim 10, wherein the liquid coolant has a first temperature at the inlet tube and a second temperature at the outlet tube, wherein the second temperature is greater than the first temperature.

12. The method of claim 10, wherein during the pumping the liquid coolant through the inlet tube into the cavity, around the micropillars and out through the outlet tube, the liquid coolant has a turbulent flow around the micropillars within the cavity.

13. The method of claim 8, wherein a first subset of the micropillars are formed containing a via extending through the micropillars and a second subset of the micropillars are formed without containing a via.

14. The method of claim 8, wherein each one of the micropillars are spaced at differing distances from each other one of the micropillars within the cavity.

15. The method of claim 8, wherein the liquid coolant comprises a glycol solution or water.

16. An apparatus comprising:
a first semiconductor package comprising:
a first semiconductor device;
a second semiconductor device; and
an integrated micro-cooling structure disposed between the first semiconductor device and the second semiconductor device;
a pumping system attached to the first semiconductor package, the pumping system comprising:
a pump;
a first tube, wherein a first side of the first tube is attached to the pump and a second side of the first tube is attached to the integrated micro-cooling structure; and
a second tube, wherein a first side of the second tube is attached to the integrated micro-cooling structure and a second side of the second tube is attached to the pump; and
a liquid coolant, wherein the liquid coolant is contained within the pumping system and within a cavity within the integrated micro-cooling structure.

17. The apparatus of claim 16, wherein the pump has a pumping power of 10 or less watts.

18. The apparatus of claim 16, wherein the pumping system is configured to accommodate the liquid coolant at a first temperature in the first tube and at a second temperature in the second tube, the second temperature being higher than the first temperature.

19. The apparatus of claim 16, wherein the pumping system is configured to accommodate the liquid coolant with a Reynolds number greater than 4,000 within the cavity.

20. The apparatus of claim 16, wherein the pumping system is attached to a second semiconductor package.
